(19) United States
(12) Patent Application Publication
(10) Pub. No.: US 2024/0183734 A1
(43) Pub. Date: Jun. 6, 2024

(54) MEMS SENSOR

(71) Applicant: ROHM CO., LTD., Kyoto (JP)

(72) Inventor: Masahiro SAKURAGI, Kyoto (JP)

(73) Assignee: ROHM CO., LTD., Kyoto (JP)

(21) Appl. No.: 18/525,746

(22) Filed: Nov. 30, 2023

(30) Foreign Application Priority Data
Dec. 5, 2022 (JP) 2022-194456

(51) Int. Cl. G01L 19/00; G01L 9/00; G01L 17/00; G01P 15/09

(52) U.S. Cl. CPC G01L 19/0092; G01L 9/0052; G01L 17/00; G01P 15/09

(57) ABSTRACT

The present disclosure provides a MEMS sensor. The MEMS sensor includes: a substrate, on which a first sensor region for an acceleration sensor is formed; a first cavity, formed in the first sensor region of the substrate; a first weight portion, including a first membrane formed on the first cavity; a beam portion, supporting the first weight portion; and a piezoresistor, formed in the beam portion. A first opposing surface of the first weight portion facing the first cavity and a second opposing surface of the beam portion facing the first cavity are formed on same plane.

### TECHNICAL FIELD

The present disclosure relates to a micro-electro-mechanical system (MEMS) sensor.

### BACKGROUND

Patent document 1 discloses a MEMS sensor, which includes a cavity and a silicon diaphragm formed on the cavity. A piezoresistor is formed on the silicon diaphragm that seals the cavity. The movement of the silicon diaphragm accompanied by a change in the pressure in the cavity is used to cause a change in a value of the piezoresistor.

### PRIOR ART DOCUMENT

[Patent publication]

[Patent document 1] Japan Patent Publication No. 2021-025966

### BRIEF DESCRIPTION OF THE DRAWINGS

FIG. 1 is a plan view of a MEMS sensor according to an embodiment of the present disclosure.

FIG. 2 is a partial cross-sectional diagram of a MEMS sensor according to an embodiment of the present disclosure and is a cross section taken along II-II in FIG. 1.

FIG. 3A is a circuit diagram of a bridge circuit formed by metal wirings and piezoresistors in an acceleration sensor region.

FIG. 3B is a circuit diagram of a bridge circuit formed by metal wirings and piezoresistors in a pressure sensor region.

FIG. 4A is a diagram illustrating a part of a manufacturing process of a MEMS sensor according to an embodiment of the present disclosure.

FIG. 4B is a diagram showing a subsequent step of FIG. 4A.

FIG. 4C is a diagram showing a subsequent step of FIG. 4B.

FIG. 4D is a diagram showing a subsequent step of FIG. 4C.

FIG. 4E is a diagram showing a subsequent step of FIG. 4D.

FIG. 4F is a diagram showing a subsequent step of FIG. 4E.

FIG. 4G is a diagram showing a subsequent step of FIG. 4F.

FIG. 4H is a diagram showing a subsequent step of FIG. 4G.

FIG. 4I is a diagram showing a subsequent step of FIG. 4H.

FIG. 5 is a diagram of a variation example of the step in FIG. 4B.

FIG. 6 is a plan view of a MEMS sensor according to another embodiment of the present disclosure.

FIG. 7 is a cross-sectional diagram illustrating a variation example of the present disclosure.

FIG. 8 is a diagram of an installation state when the MEMS sensor is used as a tire pressure sensor.

### DETAILED DESCRIPTION OF THE EMBODIMENTS

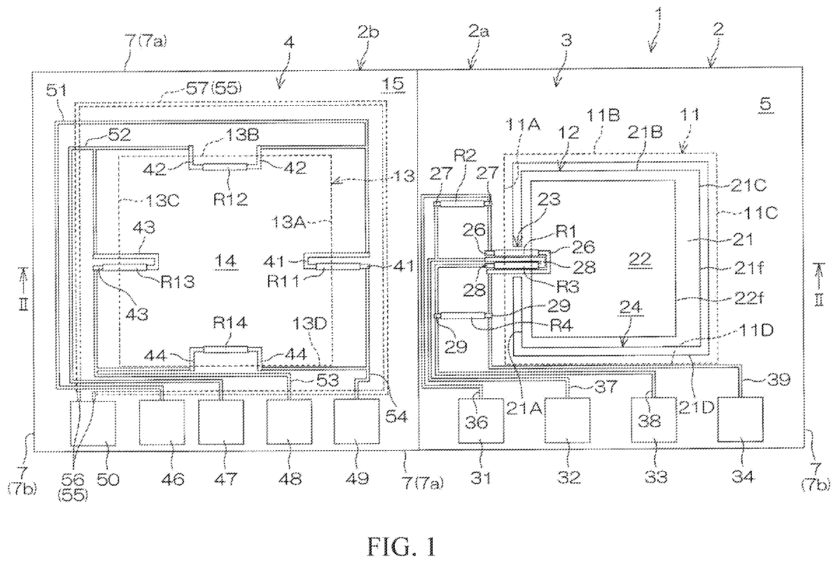

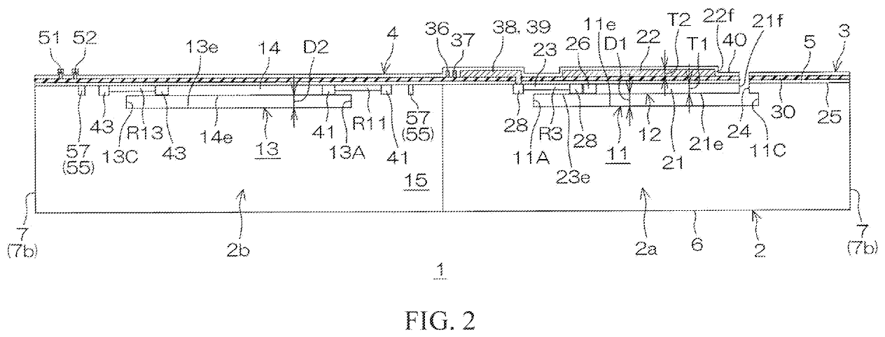

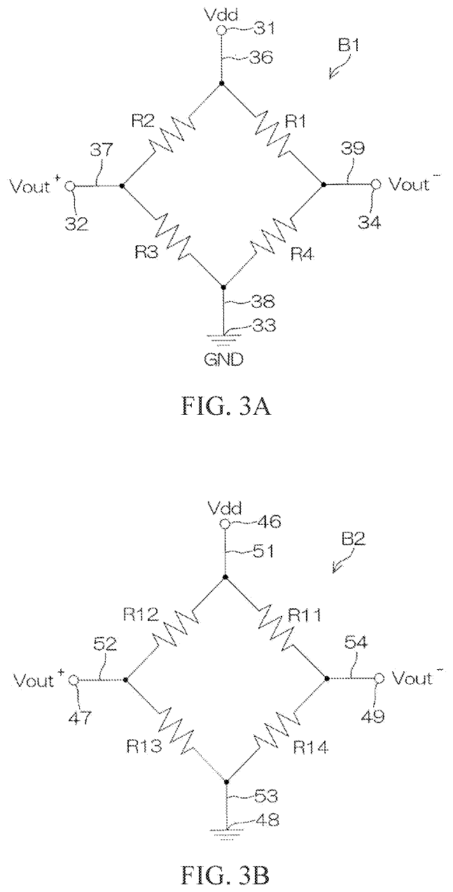

FIG. 1 shows a plan view of a micro-electro-mechanical systems (MEMS) sensor 1 according to an embodiment of the present disclosure. FIG. 2 shows a cross-sectional diagram of the MEMS sensor 1 according to an embodiment of the present disclosure and is a cross section taken along II-II in FIG. 1. FIG. 3A shows a circuit diagram of a bridge circuit B1 formed by metal wirings 36 to 39 and piezoresistors R1 to R4 in a first sensor region 2a. FIG. 3B shows a circuit diagram of a bridge circuit B2 formed by metal wirings 51 to 54 and piezoresistors R11 to R14 in a second sensor region 2b.

The MEMS sensor 1 is applicable to various types of sensors such as tire pressure monitoring systems (TPMS). The MEMS sensor 1 includes a substrate 2. The substrate 2 includes the first sensor region 2a for an acceleration sensor, and the second sensor region 2b for a pressure sensor. An acceleration sensor structure 3 serving as a single-axis acceleration sensor is formed in the first sensor region 2a. A pressure sensor structure 4 is formed in the second sensor region 2b. That is, the MEMS sensor 1 is a sensor mounted with both an acceleration sensor and a pressure sensor in one chip.

The MEMS sensor 1 detects a magnitude of an acceleration acting on the substrate 2 and a magnitude of a pressure acting on the substrate 2. When the MEMS sensor 1 is applied to a TPMS, the MEMS sensor 1 is capable of detecting, for example, both the pressure of a tire and a movement of the tire.

The substrate 2 includes a semiconductor substrate. In this embodiment, the substrate 2 is an n-type semiconductor substrate. In this embodiment, the substrate 2 is a silicon substrate. The substrate 2 has a first surface 5 and a second surface 6 on an opposite side. The first surface 5 and the second surface 6 of the substrate 2 can also be respectively referred to as a front surface and a back surface of the substrate 2. Moreover, the substrate 2 has an end surface 7. In this embodiment, the substrate 2 is formed in a quadrilateral shape in a plan view. The end surface 7 includes four end surfaces 7 forming four sides of the substrate 2 in the plan view.

In this embodiment, the substrate 2 is formed in a rectangular shape in the plan view. The four end surfaces 7 include two end surfaces 7a along a lengthwise direction of the substrate 2, and two end surfaces 7b along a widthwise direction. The first sensor region 2a and the second sensor region 2b are adjacent to each other in the lengthwise direction of the substrate 2. For example, with the first sensor region 2a that is a square in shape in the plan view and the second sensor region 2b that is a square in shape in the plan view adjacent to each other in the lengthwise direction of the substrate 2, the substrate 2 can also be formed in a rectangular shape in the plan view. In FIG. 1 and FIG. 2, the first sensor region 2a and the second sensor region 2b are adjacent. However, an element region in which another element (for example, a circuit element that detects an operation of the acceleration sensor structure 3 and the pressure sensor structure 4) is formed can also be interposed between the first sensor region 2a and the second sensor region 2b.

The end surface 7 of the substrate 2 can be referred to as a side surface of the substrate 2, or be referred to as a third surface. Moreover, a thickness of the substrate 2 is, for example, between about 100 micrometers (μm) and about 775 μm.

The substrate 2 includes a first cavity 11 formed in the first sensor region 2a, a first membrane 12 formed on the first cavity 11, a second cavity 13 formed in the second sensor region 2b, a second membrane 14 formed on the second cavity 13, and a fixing portion 15.

The first cavity 11 and the second cavity 13 are cavities formed inside the substrate 2. The first membrane 12 is, for example, film-like, and is disposed at an opening of the first cavity 11 to cover the first cavity 11 from an upper side. The second membrane 14 is, for example, film-like, and is disposed at an opening of the second cavity 13 to seal the second cavity 13. The fixing portion 15 is a part supporting the first membrane 12 and the second membrane 14. In this embodiment, a portion other than the first cavity 11, the first membrane 12, the second cavity 13 and the second membrane 14 in the substrate 2 is the fixing portion 15. The fixing portion 15 is formed to cross the first sensor region 2a and the second sensor region 2b.

The acceleration sensor structure 3 includes the first cavity 11, a first weight portion 21, a second weight portion 22 formed on the first weight portion 21, a beam portion 23 deformably supporting the first weight portion 21 and the second weight portion 22 in a thickness direction of the substrate 2, and multiple piezoresistors R1 to R4 serving as strain gauges.

As shown in FIG. 1, the first cavity 11 is formed in a substantially quadrilateral shape in the plan view. In the plan view, the first cavity 11 has a first side 11A, a second side 11B, a third side 11C and a fourth side 11D. For example, the side closest to the second sensor region 2b is the first side 11A, and the second side 11B, the third side 11C and the fourth side 11D are sequentially formed from the first side 11A.

A depth D1 of the first cavity 11 is, for example, between about 5 μm and about 20 μm. The depth D1 of the first cavity 11 can also be a distance from an opposing surface 21e of the first weight portion 21 to a bottom 11e of the first cavity 11. The depth D1 of the first cavity 11 is designed to be a depth that, even when the first weight portion 21 is closest to the bottom 11e of the first cavity 11, the opposing surface 21e of the first weight portion 21 does not abut against the bottom 11e of the first cavity 11.

As shown in FIG. 1, the first membrane 12 is formed in a substantially quadrilateral shape in the plan view. The first membrane 12 has a fixed thickness. Moreover, the thickness of the first membrane 12 is, for example, between about 3 μm and about 30 μm. Preferably, the thickness of the first membrane 12 is, for example, 7 μm.

A separation groove 24 that separates the first membrane 12 from the fixing portion 15 in the first sensor region 2a is formed between the first membrane 12 and the fixing portion 15. The separation groove 24 passes through the first membrane 12 between the first surface 5 and the first cavity 11. The separation groove 24 is formed in a region of an entirety of the sides 11A to 11D other than a portion of the sides 11A to 11D. The separation groove 24 has a substantially loop shape. A portion of the first membrane 12 separated from the fixing portion 15 and having a substantially quadrilateral shape in the plan view is the first weight portion 21. A portion of the first membrane 12 other than the first weight portion 21 is the beam portion 23.

Thus, the first membrane 12 can also include: a beam portion 23, extending as a strip or linearly from the fixing portion 15 toward an upper side of the first cavity 11; and the first weight portion 21 having a plane shape, integrally formed with the beam portion 23, having a width greater than that of the beam portion 23, and having an edge in an approaching manner along side surfaces (in this embodiment, the first to fourth sides 11A to 11D) of the first cavity 11. The separation groove 24 between the first weight portion 21 and the fixing portion 15 forms a line shape surrounding the first weight portion 21, or can have a gap with a fine width (for example, between about 5 μm and about 50 μm) that is conducive to physically separating the first weight portion 21 and the fixing portion 15. In this embodiment, the separation groove 24 is formed in a fixed width throughout a full periphery of the first weight portion 21.

By physically separating the first weight portion 21 and the fixing portion 15 by the separation groove 24 with a fine width, planar dimensions of the first weight portion 21 can be substantially the same as planar dimensions of the first cavity 11. Accordingly, the first weight portion 21 can be provided with a sufficient weight. As a result, even if a small acceleration acts on the MEMS sensor 1, the first weight portion 21 can be sufficiently deformed by its own weight, thereby detecting the acceleration with a better precision.

The first weight portion 21 is formed by the first membrane 12. The first weight portion 21 has a first side 21A, a second side 21B, a third side 21C and a fourth side 21D. For example, the side parallel to the first side 11A of the first cavity 11 is the first side 21A, and the second side 21B, the third side 21C and the fourth side 21D are sequentially formed clockwise from the first side 21A. The first weight portion 21 has the opposing surface 21e facing the bottom 11e of the first cavity 11. The opposing surface 21e is a flat surface. A thickness T1 of the first weight portion 21 (referring to FIG. 2) is consistent with the thickness of the first membrane 12. Moreover, the thickness T1 of the first weight portion 21 is, for example, between about 3 μm and about 30 μm. Preferably, the thickness T1 of the first weight portion 21 is, for example, 7 μm.

The second weight portion 22 is disposed on the first weight portion 21. As shown in FIG. 1, the second weight portion 22 is film-like, and is formed in a substantially quadrilateral shape in the plan view. In the plan view, the second weight portion 22 overlaps the first weight portion 21. In this embodiment, on the first weight portion 21, the second weight portion 22 is formed in an entire region other than a peripheral portion 21f of the first weight portion 21.

More specifically, the second weight portion 22 is formed at an inner side at a distance from the first to fourth sides 21A to 21D of the first weight portion 21, and the peripheral portion 21f of the first weight portion 21 is formed between a peripheral region 22f of the second weight portion 22 and the first to fourth sides 21A to 21D of the first weight portion 21. The peripheral portion 21f of the first weight portion 21 surrounds the second weight portion 22 in the plan view. The peripheral portion 22f of the second weight portion 22 and the peripheral portion 21f of the first weight portion 21 are not formed on the same plane. Accordingly, an area covered by the second weight portion 22 between the piezoresistors R1 to R4 formed at the beam portion 23 can be eliminated or reduced. Bending rigidity of the piezoelectric resistors R1 to R4 can be inhibited from becoming overly large due to being covered by the second weight portion 22 from above, so that the piezoresistors R1 to R4 can be bent flexibly. As a result, an acceleration detection precision can be enhanced.

In this embodiment, the second weight portion 22 is formed of metal. More specifically, the second weight portion 22 is a metal film electrically separated from various metal wirings (for example, first to fourth metal terminals 31 to 34 and the metal wirings 36 to 39 to be described below) formed in the acceleration sensor structure 3, and is in an electrically floating state. The second weight portion 22 is thinner than the first weight portion 21. In other words, the first weight portion 21 is thicker than the second weight portion 22. A thickness T2 of the second weight portion 22 (referring to FIG. 2) is, for example, between about 0.5 μm and about 25 μm.

The beam portion 23 is connected to the first weight portion 21 and the fixing portion 15. The beam portion 23 has an opposing surface 23e facing the bottom 11e of the first cavity 11. A thickness of the beam portion 23 is consistent with the thickness of the first membrane 12. The opposing surface 23e of the beam portion 23 and the opposing surface 21e of the first weight portion 21 are formed on the same plane. Thus, in a direction from the beam portion 23 to the first weight portion 21 (a direction from the left to the right on the paper) in FIG. 1, the opposing surface 23e and the opposing surface 21e are continuous without any step difference. In other words, the opposing surface 23e and the opposing surface 21e are integrally formed as a flat surface. The opposing surface 23e and the opposing surface 21e appear as linearly continuous in the cross-sectional view of FIG. 2.

In this embodiment, the number of the beam portion 23 included in one acceleration sensor structure 3 is one. The beam portion 23 is formed in a center of the first side 21A of the first weight portion 21. The beam portion 23 supports the first weight portion 21 and the second weight portion 22 in a cantilevered manner. The first weight portion 21, the second weight portion 22 and the beam portion 23 are deformed in the thickness direction of the substrate 2 along with an acceleration generated on the first surface 5 of the substrate 2.

A width (a length in a direction of the first side 11A) of the beam portion 23 is, for example, between about 20 μm and about 200 μm. A length (a length in a direction of the second side 11B and the fourth side 11D) of the beam portion 23 is, for example, between about 5 μm and about 50 μm.

The piezoresistors R1 to R4 are diffusion resistors formed on the first surface 5 by introducing an impurity such as boron (B) into the first surface 5 in the first sensor region 2a, and are also referred to as “gauges”.

The piezoresistor (a first piezoresistor) R1 and the piezoresistor (a second piezoresistor) R3 among the piezoresistors R1 to R4 are disposed at the beam portion 23. The piezoresistor R1 and the piezoresistor R3 have lengthwise shapes extending in a lengthwise direction (a direction along the second side 11B and the fourth side 11D) of the beam portion 23. The piezoresistor R1 and the piezoresistor R3 are adjacent in a widthwise direction (a direction along the first side 11A) of the beam portion 23. Both ends in a lengthwise direction of the piezoresistor R1 and both ends in a lengthwise direction of the piezoresistor R3 are consistent in the lengthwise direction (a direction along the second side 11B and the fourth side 11D) of the beam portion 23.

The piezoresistor R1 and the piezoresistor R3 cross the first weight portion 21, the beam portion 23 and the fixing portion 15 in the first sensor region 2a in the plan view. In other words, the piezoresistor R1 and the piezoresistor R3 cross the inside and outside of the first cavity 11 in the plan view. Moreover, the piezoresistor R1 and the piezoresistor R3 can also horizontally cross the lengthwise direction from the fixing portion 15 to the beam portion 23 to reach the first weight portion 21 in the plan view. End portions of the piezoresistor R1 and the piezoresistor R3 on the side of the first weight portion 21 are preferably not covered by the second weight portion 22 in the plan view, but can also be covered. In FIG. 1, an embodiment in which the end portions of the piezoresistor R1 and the piezoresistor R3 on the side of the first weight portion 21 are covered by the second weight portion 22 is shown.

The piezoresistor R2 and the piezoresistor R4 among the piezoresistors R1 to R4 are disposed at the fixing portion 15 in the first sensor region 2a. More specifically, at the sensor portion 15, the piezoresistor R2 and the piezoresistor R4 are disposed between the first side 11A of the first cavity 11 and the second sensor region 2b. The piezoresistor R2 and the piezoresistor R4 have lengthwise shapes extending in a direction along the second side 11B and the fourth side 11D.

Both end portions of the piezoresistor R1 in the lengthwise direction are connected to first contact wirings 26. One of the pair of first contact wirings 26 is connected to the piezoresistor R1 at the fixing portion 15. The other of the pair of first contact wirings 26 is connected to the piezoresistor R1 at the first weight portion 21, and horizontally crosses an interface between the first weight portion 21 and the beam portion 23 and an interface between the beam portion 23 and the fixing portion 15. The pair of first contact wirings 26 extend in the same direction. The first contact wirings 26 are diffusion wirings (p+−type region) formed on the first surface 5 by introducing a high-concentration impurity such as boron (B) to the first surface 5.

Both end portions of the piezoresistor R3 in the lengthwise direction are connected to third contact wirings 28. One of the pair of third contact wirings 28 is connected to the piezoresistor R3 at the fixing portion 15. The other of the pair of third contact wirings 28 is connected to the piezoresistor R3 at the first weight portion 21, and horizontally crosses the interface between the first weight portion 21 and the beam portion 23 and the interface between the beam portion 23 and the fixing portion 15. The pair of third contact wirings 28 extend in the same direction. The third contact wirings 28 are diffusion wirings (p⁺−type region) formed on the first surface 5 by introducing a high-concentration impurity such as boron (B) to the first surface 5.

Both end portions of the piezoresistor R2 in the lengthwise direction are connected to second contact wirings 27. The second contact wirings 27 are diffusion wirings (p⁺−type region) formed on the first surface 5 by introducing a high-concentration impurity such as boron (B) to the first surface 5.

One end portion of the piezoresistor R4 in the lengthwise direction is connected to a fourth contact wiring 29. The fourth contact wiring 29 is a diffusion wiring (p⁺−type region) formed on the first surface 5 by introducing a high-concentration impurity such as boron (B) to the first surface 5.

Referring to FIG. 2, an insulation layer 30 is formed on the first surface 5 of the substrate 2 and separated from the first surface 5 by an oxide film 25. The insulation layer 30 is interposed between the first weight portion 21 and the second weight portion 22, and electrically and physically insulates the first weight portion 21 and the second weight portion 22. The insulation layer 30 can include, for example, silicon oxide (SiO₂), or silicon nitride (SiN). The insulation layer 30 covers the first membrane 12 and the fixing portion 15 in the first sensor region 2a. Moreover, a thickness of the insulation layer 30 is, for example, between about 0.1 μm and about 2.0 μm.

Referring to FIG. 1, the acceleration sensor structure 3 further includes the metal terminals 31 to 34, and the metal wirings 36 to 39. The metal terminals 31 to 34 include a first metal terminal 31, a second metal terminal 32, a third metal terminal 33 and a fourth metal terminal 34. The metal terminals 31 and 34 are formed on the insulation layer 30. The metal terminals 31 to 34 are arranged to be separated along the end surface 7a of the substrate 2 in the plan view. Moreover, in this embodiment, the metal terminals 31 to 34 include aluminum (Al). Moreover, the first to fourth metal terminals 31 to 34 can also be respectively referred to as a voltage application terminal (Vdd), a positive voltage output terminal (Vout+), a ground terminal (GND) and a negative voltage output terminal (Vout-) according to respective connection targets.

The metal wirings (wirings) 36 to 39 are wirings for bridging the piezoresistors R1 to R4 to form the bridge circuit B1 (Wheatstone bridge) shown in FIG. 3A.

More specifically, the first metal wiring 36 is connected to the piezoresistor R1 and the piezoresistor R2 at the fixing portion 15, and is connected to the first metal terminal 31. The second metal wiring 37 is connected to the piezoresistor R2 and the piezoresistor R3 at the fixing portion 15, and is connected to the second metal terminal 32. The third metal wiring 38 is connected to the piezoresistor R3 and the piezoresistor R4 at the fixing portion 15, and is connected to the third metal terminal 33. The fourth metal wiring 39 is connected to the piezoresistor R4 and the piezoresistor R1 at the fixing portion 15, and is connected to the fourth metal terminal 34.

Referring to FIG. 1, in this embodiment, the metal wirings 36 to 39 include aluminum (Al), and are formed on the insulation layer 30. The first metal wiring 36 is separated by the insulation layer 30 and connected to the first contact wirings 26 and the second contact wirings 27, and the second metal wiring 37 is separated by the insulation layer 30 and connected to the second contact wirings 27 and the third contact wirings 28. The third metal wiring 38 is separated by the insulation layer 30 and connected to the third contact wirings 28 and the fourth contact wirings 29 (referring to FIG. 2), and the fourth metal wiring 39 is separated by the insulation layer 30 and connected to the fourth contact wiring 29 and the first contact wirings 26.

A passivation film 40 is formed on the insulation layer 30. The passivation film 40 can include, for example, silicon nitride (SiN). The passivation film 40 covers the second weight portion 22, the fixing portion 15 in the first sensor region 2a, the metal terminals 31 to 34 and the metal wirings 36 to 39. The peripheral portion 22f of the second weight portion 22 is globally covered by the passivation film 40, and insulates the second weight portion 22 from a periphery via the insulation layer 30 supporting the second weight portion 22 from below and the passivation film 40. Moreover, a thickness of the passivation film 40 is, for example, between about 0.1 μm and about 2.0 μm.

The pressure sensor structure 4 includes the second cavity 13 and the second membrane 14.

As shown in FIG. 1, the second cavity 13 is formed in a substantially quadrilateral shape in the plan view. In the plan view, the second cavity 13 has a first side 13A, a second side 13B, a third side 13C and a fourth side 13D. For example, the side closest to the first sensor region 2a is the first side 13A, and the second side 13B, the third side 13C and the fourth side 13D are sequentially formed counterclockwise from the first side 13A.

A depth D2 of the second cavity 13 is, for example, the same as the depth D1 of the first cavity 11. The depth D2 of the second cavity 13 is, for example, between about 5 μm and about 20 μm. The depth D2 of the second cavity 13 can also be a distance from an opposing surface 14e of the second membrane 14 to a bottom 13e of the second cavity 13.

As shown in FIG. 1, the second membrane 14 is formed in a substantially quadrilateral shape in the plan view. The second membrane 14 has a fixed thickness. The thickness of the second membrane 14 is the same as the thickness of the first membrane 12. The thickness of the second membrane 14 is, for example, between about 3 μm and about 30 μm. Preferably, the thickness of the second membrane 14 is, for example, 7 μm.

The second membrane 14 has the opposing surface 14e facing the bottom 13e of the second cavity 13. The second membrane 14 is deformable relative to the second cavity 13. The second membrane 14 seals the second cavity 13. In the second sensor region 2b, an interface line between the second membrane 14 and the fixing portion 15 in the second sensor region 2b has a substantially quadrilateral shape in the plan view, and is aligned with the four sides 13A to 13D of the second cavity 13 in the plan view. The second cavity 13 is sealed by the second membrane 14, and thus an inside of the second cavity 13 is kept vacuum. The second membrane 14 moves in the thickness direction of the substrate 2 along with a change in a difference of ambient atmospheric pressure relative to the vacuum environment.

The pressure sensor structure 4 further includes piezoresistors R11 to R14 serving as strain gauges. The piezoresistors R11 to R14 are diffusion resistors formed on the first surface 5 by introducing an impurity such as boron (B) into the first surface 5 in the second sensor region 2b, and are also referred to as “gauges”.

The piezoresistors R11 to R14 are substantially equidistantly arranged in a peripheral direction of the second membrane 14 having a substantially quadrilateral shape in the plan view. More specifically, in the plan view, the piezoresistor R11 is disposed on the first side 13A of the second cavity 13, the piezoresistor R12 is disposed on the second side 13B of the second cavity 13, the piezoresistor R13 is disposed on the third side 13C of the second cavity 13, and the piezoresistor 14 is disposed on the fourth side 13D of the second cavity 13.

The piezoresistor R11 and the piezoresistor R13 that face each other and are separated by a center of the second membrane 14 have lengthwise shapes extending in an opposing direction (a direction horizontally crossing the first side 13A and the third side 13C of the second cavity 13) of the piezoresistor R11 and the piezoresistor R13. The piezoresistor R11 and the piezoresistor R13 cross the second membrane 14 and the fixing portion 15 in the second sensor region 2b in the plan view. In other words, the piezoresistor R11 and the piezoresistor R13 cross the inside and outside of the second cavity 13 in the plan view.

On the other hand, the piezoresistor R12 and the piezoresistor R14 that face each other and are separated by the center of the second membrane 14 have lengthwise shapes extending in a direction orthogonal to the opposing direction (a direction along the second side 13B and the fourth side 13D of the second cavity 13) of the piezoresistor R12 and the piezoresistor R14. The piezoresistor R12 and the piezoresistor R14 are converged on an inner side of the second membrane 14 in the plan view.

Both end portions of the piezoresistor R11 in the lengthwise direction are connected to fifth contact wirings 41. One of the pair of fifth contact wirings 41 is connected to the piezoresistor R11 at the fixing portion 15. The other of the pair of fifth contact wirings 41 is connected to the piezoresistor R11 at the second membrane 14, and horizontally crosses an interface between the second membrane 14 and the fixing portion 15. The pair of fifth contact wirings 41 extend in the same direction. The fifth contact wirings 41 are diffusion wirings (p⁺−type region) formed on the first surface 5 by introducing a high-concentration impurity such as boron (B) to the first surface 5.

Both end portions of the piezoresistor R12 in the lengthwise direction are connected to sixth contact wirings 42. The pair of sixth contact wirings 42 are connected to the piezoresistor R12 at the second membrane 14, and horizontally cross the interface between the second membrane 14 and the fixing portion 15 and extend in the same direction. The sixth contact wirings 42 are diffusion wirings (p⁺−type region) formed on the first surface 5 by introducing a high-concentration impurity such as boron (B) to the first surface 5.

Both end portions of the piezoresistor R13 in the lengthwise direction are connected to seventh contact wirings 43. One of the pair of seventh contact wirings 43 is connected to the piezoresistor R13 at the fixing portion 15. The other of the pair of seventh contact wirings 43 is connected to the piezoresistor R13 at the second membrane 14, and horizontally crosses the interface between the second membrane 14 and the fixing portion 15. The pair of seventh contact wirings 43 extend in the same direction. The seventh contact wirings 43 are diffusion wirings (p⁺−type region) formed on the first surface 5 by introducing a high-concentration impurity such as boron (B) to the first surface 5.

Both end portions of the piezoresistor R14 in the lengthwise direction are connected to eighth contact wirings 44. The pair of eighth contact wirings 44 are connected to the piezoresistor R14 at the second membrane 14, and horizontally cross the interface between the second membrane 14 and the fixing portion 15 and extend in the same direction. The eighth contact wirings 44 are diffusion wirings (p⁺−type region) formed on the first surface 5 by introducing a high-concentration impurity such as boron (B) to the first surface 5.

The insulation layer 30 covers the second membrane 14 and the fixing portion 15 in the second sensor region 2b. More specifically, the insulation layer 30 globally covers an entirety of the first surface 5 in the first sensor region 2a and the second sensor region 2b.

The pressure sensor structure 4 further includes metal terminals 46 to 50, and the metal wirings 51 to 54. The metal terminals 46 to 50 include a fifth metal terminal 46, a sixth metal terminal 47, a seventh metal terminal 48, an eighth metal terminal 49 and a ninth metal terminal 50. The metal terminals 46 to 50 are formed on the insulation layer 30. The metal terminals 46 to 50 are arranged to be separated along the end surface 7a of the substrate 2 in the plan view. Moreover, in this embodiment, the metal terminals 46 to 50 include aluminum (Al). Moreover, the fifth to eighth metal terminals 46 to 49 can also be respectively referred to as a voltage application terminal (Vdd), a positive voltage output terminal (Vout+), a ground terminal (GND) and a negative voltage output terminal (Vout-) according to respective connection targets.

The metal wirings 51 to 54 are wirings for bridging the piezoresistors R11 to R14 to form the bridge circuit B2 (Wheatstone bridge) shown in FIG. 3B.

More specifically, the fifth metal wiring 51 is connected to the piezoresistor R11 and the piezoresistor R12 at the fixing portion 15, and is connected to the fifth metal terminal 46. The sixth metal wiring 52 is connected to the piezoresistor R12 and the piezoresistor R13 at the fixing portion 15, and is connected to the sixth metal terminal 47. The seventh metal wiring 53 is connected to the piezoresistor R13 and the piezoresistor R14 at the fixing portion 15, and is connected to the seventh metal terminal 48. The eighth metal wiring 54 is connected to the piezoresistor R14 and the piezoresistor R11 at the fixing portion 15, and is connected to the eighth metal terminal 49.

Referring to FIG. 1, in this embodiment, the metal wirings 51 to 54 include aluminum (Al), and are formed on the insulation layer 30. The fifth metal wiring 51 is separated by the insulation layer 30 and connected to the fifth contact wirings 41 and the sixth contact wirings 42, and the sixth metal wiring 52 is separated by the insulation layer 30 and connected to the sixth contact wirings 42 and the seventh contact wirings 43. The seventh metal wiring 53 is separated by the insulation layer 30 and connected to the seventh contact wirings 43 and the eighth contact wirings 44, and the eighth metal wiring 54 is separated by the insulation layer 30 and connected to the eighth contact wirings 44 and the fifth contact wirings 41.

Moreover, the ninth metal terminal 50 is connected to the ninth wiring 55. Referring to FIG. 1, the ninth wiring 55 includes a metal wiring 56 formed on the insulation layer 30, and a diffusion wiring 57 formed on the first surface 5 of the substrate 2. Referring to FIG. 1 and FIG. 2, the diffusion wiring 57 is formed to have a loop shape surrounding the second cavity 13 of the pressure sensor structure 4 in the plan view. Moreover, the diffusion wiring 57 can also pass through below the metal terminals 46 to 50. That is, the diffusion wiring 57 can also overlap at least one of the metal terminals 46 to 50 in the plan view.

The passivation film 40 on the insulation layer 30 covers the second membrane 14, the fixing portion 15 in the second sensor region 2b, the metal terminals 46 to 50 and the metal wirings 51 to 54 and 56. More specifically, the passivation film 40 globally covers an entirety of structures on the insulation layer 30 in the first sensor region 2a and the second sensor region 2b.

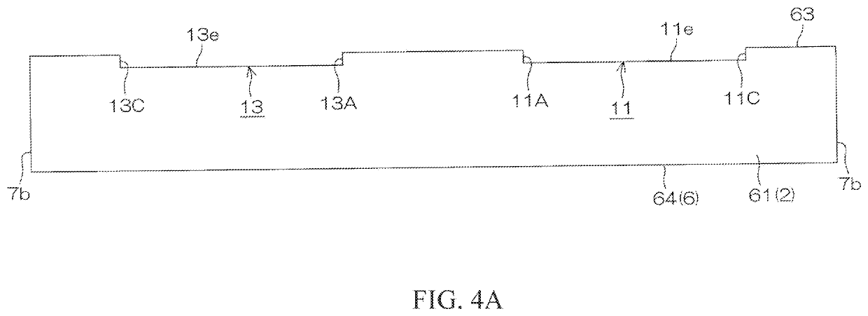

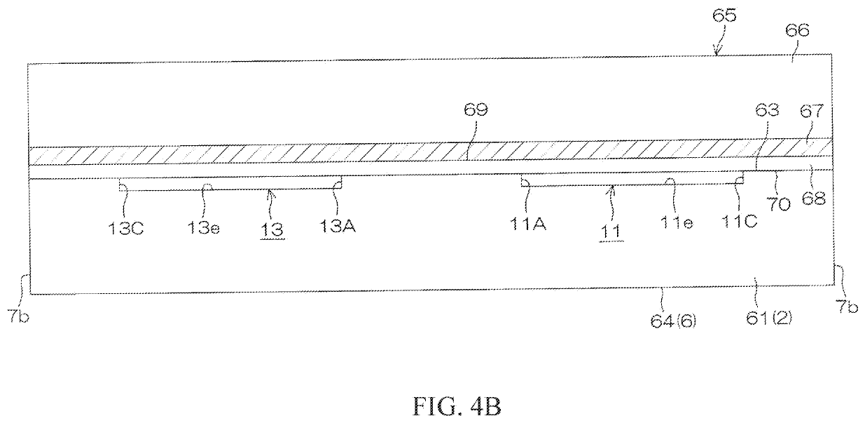

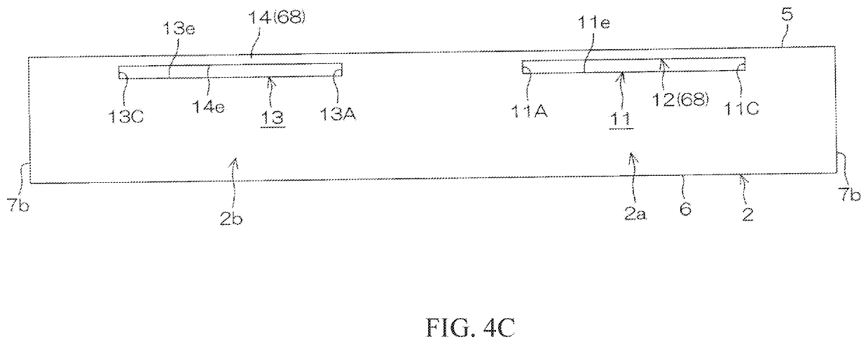

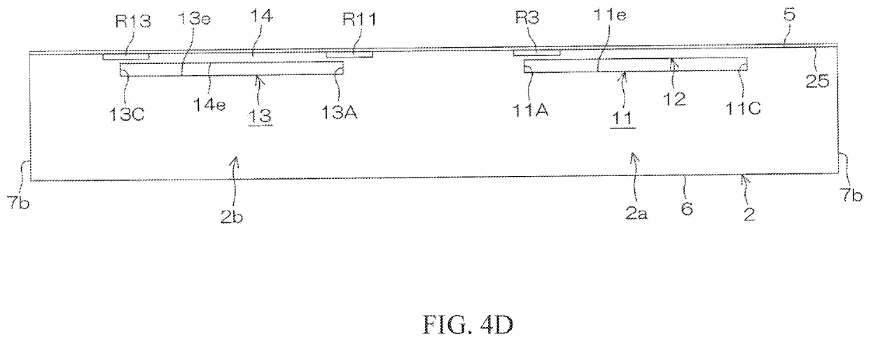

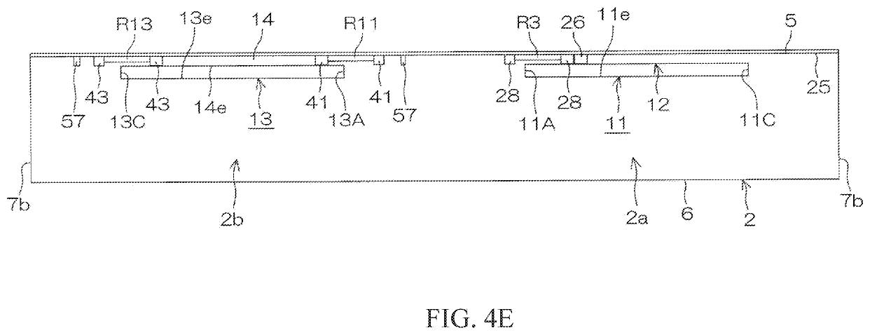

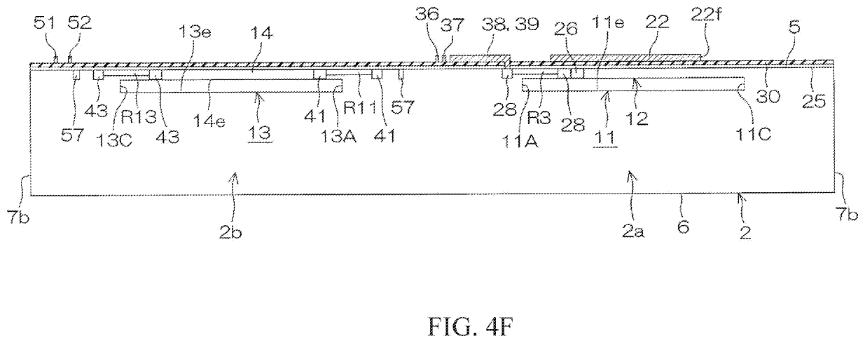

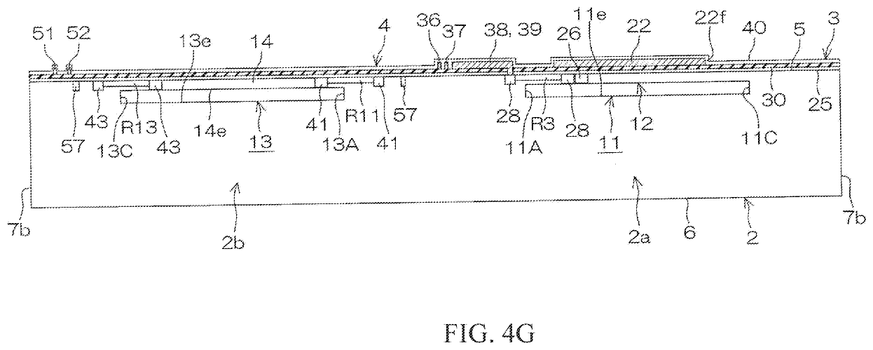

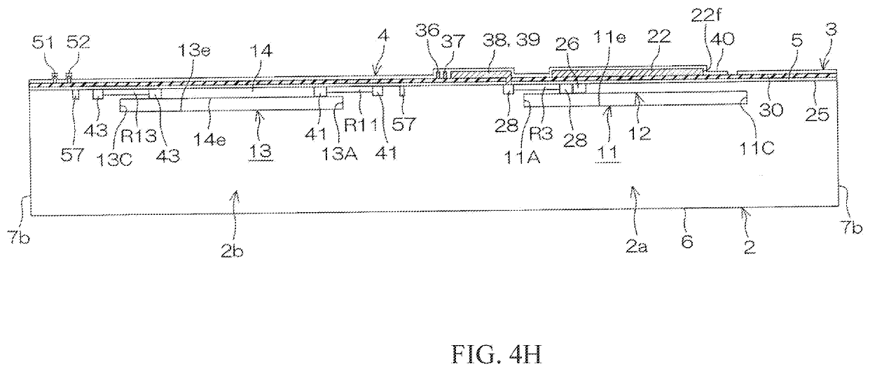

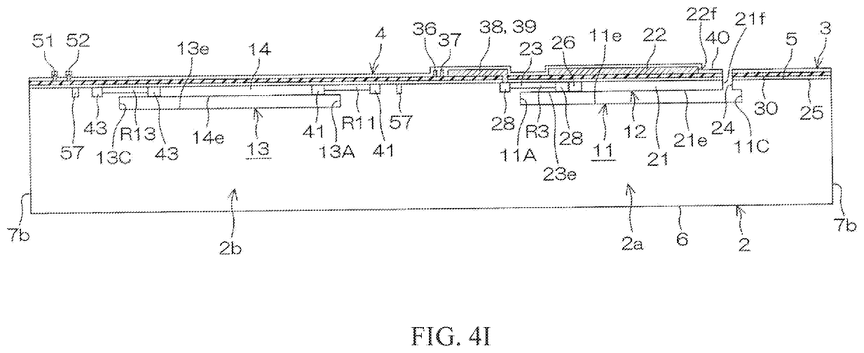

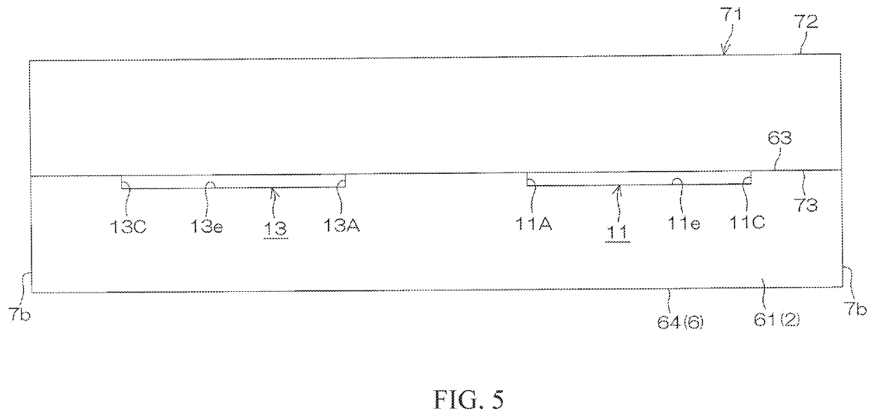

FIG. 4A to FIG. 4I show diagrams of a part of a manufacturing process of the MEMS sensor 1 according to an embodiment of the present disclosure. FIG. 5 shows a diagram of a variation example of the process in FIG. 4B.

To manufacture the MEMS sensor 1, for example, as shown in FIG. 4A, a first silicon substrate 61 that becomes the substrate 2 is prepared. The first silicon substrate 61 is, for example, an n-type semiconductor chip. The first silicon substrate 61 has a first surface 63 and a second surface 64. In this embodiment, the first surface 63 of the first silicon substrate 61 is a (100) surface and the second surface 64 is a (100) surface. The first surface 63 of the first silicon substrate 61 forms the first cavity 11 and the second cavity 13. The first cavity 11 and the second cavity 13 can also be formed by selectively performing dry etching on the first surface 63 of the first silicon substrate 61.

Next, as shown in FIG. 4B, a silicon-on-insulator (SOI) substrate 65 is prepared. The SOI substrate 65 is a chip including a silicon-containing support substrate 66, a buried oxide (BOX) layer 67 on the support substrate 66, and a silicon-containing active layer 68 on the BOX layer 67. For example, a thickness of the support substrate 66 is between about 625 μm and about 775 μm, a thickness of the BOX layer 67 is between about 0.5 μm and about 2.0 μm, and a thickness of the active layer 68 is between about 3 μm and about 30 μm. The active layer 68 has a first surface 69 connected to the BOX layer 67 and a second surface 70 on an opposite side. In this embodiment, the second surface 70 of the active layer 68 is a (110) surface. Moreover, the SOI substrate 65 is vertically inverted such that the SOI substrate 65 is bonded on the first silicon substrate 61 to have the second surface 70 of the active layer 68 be connected to the first surface 63 of the first silicon substrate 61. Then, an annealing process is performed at a temperature of, for example, 1000° C. to 1200° C. for 30 to 90 minutes. Accordingly, Si—Si direct bonding is implemented between the first silicon substrate 61 and the SOI substrate 65.

Moreover, a substrate bonded to the first silicon substrate 61 can also be a second silicon substrate 71 (silicon chip) as shown in FIG. 5. For example, a thickness of the second silicon substrate 71 can be between about 625 μm and about 775 μm. The second silicon substrate 71 has a first surface 72 and a second surface 73 on an opposite side. The second surface 73 of the second silicon substrate 71 is a (110) surface. In this case, by connecting the second surface 73 of the second silicon substrate 71 to the first surface 63 of the first silicon substrate 61, the second silicon substrate 71 is bonded on the first silicon substrate 61 to bond the first silicon substrate 61 to the second silicon substrate 71. Accordingly, Si—Si direct bonding is implemented between the first silicon substrate 61 and the second silicon substrate 71.

Next, as shown in FIG. 4C, the support substrate 66 and the BOX layer 67 are removed from the SOI substrate 65. The support substrate 66 and the BOX layer 67 can be removed by means of, for example, cutting and etching. Then, the active layer 68 is processed until a desired thickness (the thickness of the first membrane 12 and the second membrane 14) is obtained. Thinning of the active layer 68 can also be performed by means of cutting, etching and grinding.

Moreover, if the active layer 68 in a desired thickness is formed in advance in a phase of the SOI substrate 65, thinning of the active layer 68 can also be omitted after removing the BOX layer 67. Accordingly, the substrate 2 is formed. In the substrate 2, the film-like first membrane 12 is formed on the first cavity 11, and the film-like second membrane 14 is formed on the second cavity 13.

On the other hand, when the second silicon substrate 71 is used in substitution for the SOI substrate 65, the second silicon substrate 71 is thinned by means of cutting, etching or grinding to a desired thickness (the thickness of the first membrane 12 and the second membrane 14).

Moreover, the second surface 70 of the support substrate 66 connected with the first surface 63 of the first silicon substrate 61 and the second surface 73 of the second silicon substrate 71 can also be set to the (100) surface identical to the first surface 63 instead of being (110) surfaces.

Next, as shown in FIG. 4D, an oxide film 25 is formed on the first surface 5 of the substrate 2. In addition, impurity ions (boron (B) in this embodiment) are selectively injected to the first surface 5 of the substrate 2, and an annealing process is performed. Accordingly, the piezoresistors R1 to R4 and the piezoresistors R11 to R14 are formed on the first surface 5 of the substrate 2.

Next, as shown in FIG. 4E, impurity ions (boron (B) in this embodiment) are selectively injected to the first surface 5 of the substrate 2, and an annealing process is performed. Accordingly, the contact wirings 26 to 29 and the contact wirings 41 to 44 are formed on the first surface 5 of the substrate 2. In addition, impurity ions (phosphorus (P) in this embodiment) are selectively injected to the first surface 5 of the substrate 2, and an annealing process is performed. Accordingly, the diffusion wiring 57 is formed on the first surface 5 of the substrate 2.

Next, as shown in FIG. 4F, the insulation layer 30 is formed on the first surface 5 of the substrate 2 by means of, for example, chemical vapor deposition (CVD). Next, the metal terminals 31 to 34, the metal wirings 36 to 39, the metal terminals 46 to 50, the metal wirings 51 to 54 and the second weight portion 22 are formed on the insulation layer 30 by means of, for example, sputtering and patterning.

Next, as shown in FIG. 4G, the passivation film 40 covering the metal terminals 31 to 34, the metal wirings 36 to 39, the metal terminals 46 to 50, the metal wirings 51 to 54 and the second weight portion 22 are formed on the insulation layer 30. The passivation film 40 also covers the first membrane 12 and the second membrane 14. The passivation film 40 is, for example, silicon nitride (SiN) and formed by means of CVD.

Next, as shown in FIG. 4H, a portion of the passivation film 40 is selectively removed by means of etching.

Next, as shown in FIG. 4I, a portion of the insulation layer 30, a portion of the oxide film 25 and a portion of the substrate 2 are selectively removed by means of etching. Accordingly, the peripheral portion of the first membrane 12 is selectively removed to form the separation groove 24. The first weight portion 21 and the beam portion 23 are divided by the separation groove 24. Then, the MEMS sensor 1 is obtained by cutting the substrate 2 into individual chip sizes.

Referring to FIG. 1 and FIG. 2, in the acceleration sensor structure 3 of the MEMS sensor 1, the piezoresistors R1 and R3 are formed at the beam portion 23 supporting the first weight portion 21. When an acceleration in the thickness direction of the substrate 2 acts on the first weight portion 21, the first weight portion 21 is deformed in the thickness direction of the substrate 2, and the beam portion 23 extends/contracts along with such deformation. With the extending/contracting of the beam portion 23, silicon crystals constituting the piezoresistors R1 and R3 are strained, thereby causing a change in resistance values of the piezoresistors R1 and R3. When a constant bias voltage is applied to the voltage application terminal (the first metal terminal 31), a change occurs in a voltage between output terminals (the second and fourth metal terminals 32 and 34) according to the change in the resistance values of the piezoresistors R1 and R3. Thus, a magnitude of the acceleration in the thickness direction of the substrate 2 generated on the MEMS sensor 1 can be detected according to the change in the voltage.

Moreover, the opposing surface 21e of the first weight portion 21 and the opposing surface 23e of the beam portion 23 are formed on the same plane. When the acceleration acts on the substrate 2, the first weight portion 21 is deformed in the thickness direction of the substrate 2. The opposing surface 21e of the first weight portion 21 does not protrude further toward the bottom 11e of the first cavity 11 than the opposing surface 23e of the beam portion 23. Thus, when the first weight portion 21 is deformed, the opposing surface 21e of the first weight portion 21 can be prevented from coming into contact with the bottom 11e of the first cavity 11. Thus, it is not necessary to increase the depth of the first cavity 11.

Moreover, the acceleration sensor structure 3 includes the second weight portion 22. That is, the beam portion 23 supports both of the first weight portion 21 and the second weight portion 22. An overall weight of a weight supported by the beam portion 23 can be adjusted by adjusting a weight of the second weight portion 22. Even if the weight of the first weight portion 21 used as a weight is insufficient, the overall weight of the weight can be adjusted to a desired weight by additionally providing the second weight portion 22.

Moreover, the multiple piezoresistors R1 and R3 are formed in the beam portion 23. Since the extending/contracting of the beam portion 23 is detected through the multiple piezoresistors R1 and R3, the acceleration acting on the substrate 2 can be detected with a higher precision.

Moreover, both of the first weight portion 21 and the second weight portion 22 are supported by one single beam portion 23. Thus, a degree of extending/contracting of the beam portion 23 accompanied with the deformation of the first weight portion 21 and the second weight portion 22 can be increased, so that the acceleration acting on the substrate 2 can be detected with a higher precision.

On the other hand, in the pressure sensor structure 4 of the MEMS sensor 1, when the second membrane 14 receives a pressure (for example, a gas pressure) from the first surface 5, the second membrane 14 is deformed in the thickness direction of the substrate 2 due to a pressure difference between the inside and outside of the second cavity 13. With the deformation, silicon crystals constituting the piezoresistors R11 to R14 are strained, thereby causing a change in resistance values of the piezoresistors R11 to R14. For example, when a constant bias voltage is applied to the voltage application terminal (the fifth metal terminal 46), a change occurs in a voltage between the output terminals (the sixth metal terminal 47 and the eighth metal terminal 49) according to the change in the resistance values of the piezoresistors R11 to R14. Thus, a magnitude of the pressure generated on the MEMS sensor 1 can be detected according to the change in the voltage.

In the MEMS sensor 1, in addition to the first sensor region 2a for an acceleration sensor, the second sensor region 2b for a pressure sensor is also formed in the substrate 2. By forming the acceleration sensor structure 3 in the first sensor region 2a and forming the pressure sensor structure 4 in the second sensor region 2b, the acceleration generated on the MEMS sensor 1 as well as a pressure acting on the MEMS sensor 1 can be detected. That is, the MEMS sensor 1 capable of detecting both a pressure and an acceleration by using one chip can be provided. Thus, compared to situations in which chips for two types of sensors including a pressure sensor and an acceleration sensor are prepared, costs can be reduced. Moreover, compared to situations in which chips for two types of sensors including a pressure sensor and an acceleration sensor are mounted, an area needed for mounting sensors can be reduced.

Moreover, referring to FIG. 2, in this embodiment, the depth D1 of the first cavity 11 is the same as the depth D2 of the second cavity 13. Since the depths of the first cavity 11 and the second cavity 13 are the same, the first cavity 11 and the second cavity 13 can be formed in one process, and so two cavities including the first cavity 11 and the second cavity 13 can be easily formed.

FIG. 6 shows a plan view of a MEMS sensor 201 according to another embodiment of the present disclosure.

FIG. 6 shows a plan view of a main part of the MEMS sensor 201 according to another embodiment of the present disclosure. The MEMS sensor 201 differs from the MEMS sensor 1 of the embodiment in that, an acceleration sensor structure 203 includes multiple beams 223. In FIG. 6, structures that are common with those of the embodiment are provided with the same reference numerals as those in FIG. 1 to FIG. 5, and related description is omitted.

The multiple beams 223 include two beams 223A and 223B. The beams 223A and 223B support the first weight portion 21 and the second weight portion 22 in a cantilevered manner. The two beams 223A and 223B are aggregated on the first side 21A of the first weight portion 21. The separation groove 24 having a substantially loop shape includes a linear groove 224 along the first side 21A (along the first side 11A of the first cavity 11) of the first weight portion 21. The two beams 223A and 223B face each other and are separated by the linear groove 224 in a direction of the first side 11A of the first cavity 11. The two beams 223A and 223B are arranged to be separated along the first side 21A on the first side 21A of the first weight portion 21. Opposing surfaces of the two beams 223A and 223B facing the bottom 13e of the first cavity 11 and the opposing surface 21e of the first weight portion 21 are all formed on the same plane.

The piezoresistor R1 is formed in the beam 223A. The piezoresistor R3 is formed in the beam 223B. That is, the two piezoresistors R1 and R3 are separately formed in the two beams 223A and 223B.

According to the embodiment in FIG. 6, support is provided by the multiple beams 223A and 223B, and so the first weight portion 21 and the second weight portion 22 can be supported by a higher strength. Moreover, the multiple beams 223A and 223B are aggregated on one side (the first side 21A) of the first weight portion 21, and so the multiple beams 223A and 223B support the first weight portion 21 and the second weight portion 22 in a cantilevered manner. Owing to the cantilevered support, a degree of extending/contracting generated in the beams 223A and 223B accompanied with the deformation of the first weight portion 21 and the second weight portion 22 can be increased, and so the acceleration acting on the substrate 2 can be detected with a higher precision.

In the embodiment in FIG. 6, the multiple beams 223A and 223B are not necessarily aggregated on one side of the first weight portion 21, but can be distributed and disposed on the multiple first to fourth sides 21A to 21D of the first weight portion 21. The number of the multiple beams 223A and 223B is set to two, and can also be three or more. In this case, the number of the piezoresistors R1 and R3 formed in the beams 223A and 223B is preferably two.

Multiple embodiments of the disclosure are described above; however, the disclosure can also be implemented by yet another embodiment.

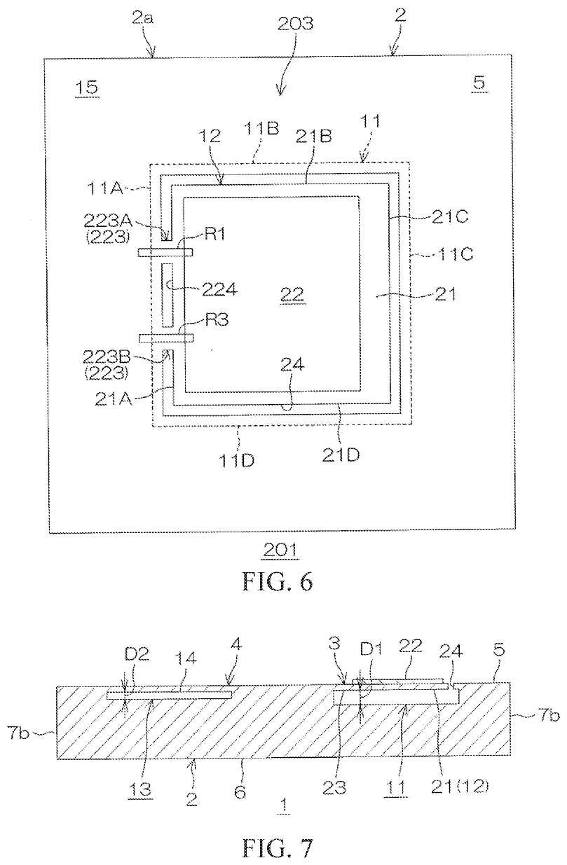

For example, as shown in FIG. 7, the depth D1 of the first cavity 11 can be different from the depth D2 of the second cavity 13. As shown in FIG. 7, the depth D1 of the first cavity 11 can be deeper than the depth D2 of the second cavity 13. In this case, when the first weight portion 21 is deformed, the first weight portion 21 can be reliably prevented from coming into contact with the bottom 11e of the first cavity 11. Conversely, the depth D2 of the second cavity 13 can also be deeper than the depth D1 of the first cavity 11. Moreover, FIG. 7 is a diagram to further schematically depict FIG. 2 in order to compare the depth D1 of the first cavity 11 with the depth D2 of the second cavity 13, and a part of the configuration of the acceleration sensor structure 3 and the pressure sensor structure 4 is omitted.

Moreover, in one acceleration sensor structure 3, the number of the piezoresistors formed in the beam portion (the beam portion 23, or the beams 223A and 223B) is set to two, and can also be set to one or three or more. When the number of the piezoresistor formed in the beam portion is set to one, the piezoresistor R1 or the piezoresistor R3 can also be formed in the beam portion.

Moreover, in the acceleration sensor structure 3, a piezoelectric element can also be used in substitution for the piezoresistor (the piezoresistors R1 to R4). Similarly, in the pressure sensor structure 4, a piezoelectric element can also be used in substitution for the piezoresistor (the piezoresistors R11 to R14).

Moreover, in the embodiments above, the second weight portion 22 made of metal is described; however, the second weight portion 22 is not limited to being metal, and can also be polysilicon, an oxide film, and a nitride film. The oxide film can be silicon oxide (SiO₂). The nitride film can be silicon nitride (SiN).

Moreover, the second weight portion 22 can have a thickness the same as that of the first weight portion 21, or can be thicker than the first weight portion 21. Alternatively, a ratio of a configuration area of the second weight portion 22 on the first weight portion 21 can be less than a ratio shown in FIG. 1. In this case, the shape of the second weight portion 22 is not limited to being a substantially quadrilateral shape in the plan view.

When the weight of the first weight portion 21 serving as a weight is sufficient, the second weight portion 22 can be omitted.

Moreover, the MEMS sensor 1 can also be a sensor in one chip functioning exclusively as a pressure sensor, but is not a sensor mounted with both an acceleration sensor and a pressure sensor. In this case, the pressure sensor can be formed by the first sensor region 2a of the substrate 2 and the acceleration sensor structure 3 in one chip.

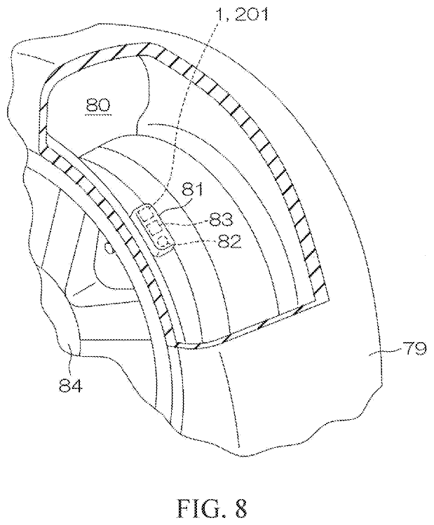

FIG. 8 shows a diagram of an installation state when the MEMS sensors 1, 201 are used as a TPMS. In FIG. 8, a part of a tire 79 of a vehicle is removed to represent an inside of the tire 79.

The MEMS sensors 1, 201 can be used for various purposes of detecting a gas pressure and acceleration, for example, used as a TPMS of a vehicle. In particular, the MEMS sensors 1, 201 include the pressure sensor structure 4, and so a direct pressure detection system that directly detects a pressure of an internal space 80 (a space between the tire 79 and a rim 84) of the tire 79 can be assembled.

The MEMS sensors 1, 201 can also be assembled into a sensor module 81 including a battery 82 and a transmitter 83. The sensor module 81 can also be mounted on a surface of the rim 84 of the internal space 80 of the tire 79, as shown in FIG. 8. The sensor module 81 uses the pressure sensor structure 4 of the MEMS sensors 1, 201 to directly detect the gas pressure of the tire 79, and wirelessly transmits the information from the transmitter 83 to a receiver (not shown) at a vehicle body, accordingly notifying a driver of an anomaly. Further, in addition to the pressure sensor structure 4 in the sensor module 81, the acceleration sensor structure 3 can also be built in. Thus, when a change in the acceleration is drastic as a result of vibration or impact received by the tire 79 during driving while the gas pressure is decreased, the change can also be detected to notify the driver of the decreased gas pressure.

Moreover, the transmitter 83 in FIG. 8 can also be built in the MEMS sensors 1, 201. Thus, a space used by the transmitter 83 in the sensor module 81 can be omitted, so that the sensor module 81 can be miniaturized. Moreover, the MEMS sensors 1, 201 or the sensor module 81 can also be further built in with a temperature sensor that detects a temperature inside a tire.

The features provided in the notes below can be extracted from the detailed description and the drawings of the present disclosure.

### [Note 1-1]

A MEMS sensor (1, 201), comprising:
a substrate (2), on which a first sensor region (2a) for an acceleration sensor (3) is formed;
a first cavity (11), formed in the first sensor region (2a) of the substrate (2);
a first weight portion (21), including a first membrane (12) formed on the first cavity (11);
a beam portion (23), supporting the first weight portion (21); and
a piezoresistor (R1, R3), formed in the beam portion (23), wherein
a first opposing surface (21e) of the first weight portion (21) facing the first cavity (11) and a second opposing surface (23e) of the beam portion (23) facing the first cavity (11) are formed on the same plane.

According to the configuration, the piezoresistor (R1, R3) is formed in the beam portion (23) supporting the first weight portion (21) including the first membrane (12), and the first opposing surface (21e) of the first weight portion (21) and the second opposing surface (23e) of the beam portion (23) are formed on the same plane. The first weight portion (21) receives an acceleration acting in the first cavity (11) and is deformed, such that the beam portion (23) extends/contracts, and a change occurs in an output of the piezoresistor (R1, R3). The first opposing surface (21e) of the first weight portion (21) does not protrude further toward a bottom (11e) of the first cavity (11) than the second opposing surface (23e) of the beam portion (23), and so the first opposing surface (21e) of the first weight portion (21) does not easily come into contact with the bottom (11e) of the first cavity (11). Accordingly, an acceleration can be well detected.

### [Note 1-2]

The MEMS sensor (1, 201) according to Note 1-1, further comprising a second weight portion (22) formed on the first membrane (12).

### [Note 1-3]

The MEMS sensor (1, 201) according to Note 1-2, wherein the second weight portion (22) is one of polysilicon, metal, oxide film, and nitride film.

### [Note 1-4]

The MEMS sensor (1, 201) according to Note 1-2 or Note 1-3, wherein the first weight portion (21) is thicker than the second weight portion (22).

### [Note 1-5]

The MEMS sensor (1, 201) according to any one of Note 1-1 to Note 1-4, wherein the beam portion (23) deformably supports the first weight portion (21) in a thickness direction of the substrate (2).

### [Note 1-6]

The MEMS sensor (1, 201) according to any one of Note 1-1 to Note 1-5, wherein the piezoresistor (R1, R3) includes a first piezoresistor (R1) and a second piezoresistor (R3), and the MEMS sensor (1, 201) further includes a wiring (36 to 39) electrically connected to the first piezoresistor (R1) and the second piezoresistor (R3), wherein the wiring (36 to 39) forms a bridge circuit including the first piezoresistor (R1) and the second piezoresistor (R3).

### [Note 1-7]

The MEMS sensor (1, 201) according to Note 1-6, wherein an output of the bridge circuit (B1) is used to detect an acceleration in a thickness direction of the substrate (2) by an acceleration sensor (3).

### [Note 1-8]

The MEMS sensor (1) according to any one of Note 1-1 to Note 1-7, wherein the beam portion (23) is singular.

### [Note 1-9]

The MEMS sensor (1, 201) according to Note 1-8, wherein the piezoresistor (R1, R3) includes a first piezoresistor (R1) and a second piezoresistor (R3).

### [Note 1-10]

The MEMS sensor (201) according to any one of Note 1-1 to Note 1-7, wherein the beam portion (23) includes a plurality of beams (223).

### [Note 1-11]

The MEMS sensor (201) according to Note 1-10, wherein the piezoresistor (R1, R3) includes a first piezoresistor (R1) and a second piezoresistor (R3), and the first piezoresistor (R1) and the second piezoresistor (R3) are formed separately from two (223A, 223B) of the plurality of beams (223).

### [Note 1-12]

The MEMS sensor (201) according to Note 1-10, wherein the first weight portion (21) is formed in a quadrilateral shape in a plan view, and the plurality of beams (223A, 223B) are aggregated on one side (21A) of the first weight portion (21).

### [Note 1-13]

The MEMS sensor (1, 201) according to any one of Note 1-1 to Note 1-12, a second sensor region (2b) for a pressure sensor (4) is formed on the substrate (2), and the MEMS sensor (1, 201) further includes:
a second cavity (13), formed in the second sensor region (2b) of the substrate (2); and
a second membrane (14), formed on the second cavity (13).

### [Note 1-14]

The MEMS sensor (1, 201) according to Note 1-13, wherein a depth (D1) of the first cavity (11) and a depth (D2) of the second cavity (13) are different.

### [Note 1-15]

The MEMS sensor (1, 201) according to Note 1-13, wherein a depth (D1) of the first cavity (11) and a depth (D2) of the second cavity (13) are the same.

1. A MEMS sensor, comprising:
a substrate, on which a first sensor region for an acceleration sensor is formed;
a first cavity, formed in the first sensor region of the substrate;
a first weight portion, including a first membrane formed on the first cavity;
a beam portion, supporting the first weight portion; and
a piezoresistor, formed in the beam portion, wherein
a first opposing surface of the first weight portion facing the first cavity and a second opposing surface of the beam portion facing the first cavity are formed on same plane.

2. The MEMS sensor of claim 1, further comprising a second weight portion formed on the first membrane.

3. The MEMS sensor of claim 2, wherein the second weight portion is one of polysilicon, metal, oxide film, and nitride film.

4. The MEMS sensor of claim 2, wherein the first weight portion is thicker than the second weight portion.

5. The MEMS sensor of claim 1, wherein the beam portion deformably supports the first weight portion in a thickness direction of the substrate.

6. The MEMS sensor of claim 1, wherein
the piezoresistor includes a first piezoresistor and a second piezoresistor, and
the MEMS sensor further includes a wiring electrically connected to the first piezoresistor and the second piezoresistor, wherein the wiring forms a bridge circuit including the first piezoresistor and the second piezoresistor.

7. The MEMS sensor of claim 6, wherein an output of the bridge circuit is used to detect acceleration in a thickness direction of the substrate by an acceleration sensor.

8. The MEMS sensor of claim 1, wherein the beam portion is singular.

9. The MEMS sensor of claim 8, wherein the piezoresistor includes a first piezoresistor and a second piezoresistor.

10. The MEMS sensor of claim 1, wherein the beam portion includes a plurality of beams.

11. The MEMS sensor of claim 10, wherein
the piezoresistor includes a first piezoresistor and a second piezoresistor, and
the first piezoresistor and the second piezoresistor are formed separately from two of the plurality of beams.

12. The MEMS sensor of claim 10, wherein
the first weight portion is formed in a quadrilateral shape in a plan view, and
the plurality of beams are aggregated on one side of the first weight portion.

13. The MEMS sensor of claim 1, wherein
a second sensor region for a pressure sensor is formed on the substrate, and
the MEMS sensor further includes:
a second cavity, formed in the second sensor region in the substrate; and
a second membrane, formed on the second cavity.

14. The MEMS sensor of claim 2, wherein
a second sensor region for a pressure sensor is formed on the substrate, and
the MEMS sensor further includes:
a second cavity, formed in the second sensor region in the substrate; and
a second membrane, formed on the second cavity.

15. The MEMS sensor of claim 5, wherein
a second sensor region for a pressure sensor is formed on the substrate, and
the MEMS sensor further includes:
a second cavity, formed in the second sensor region in the substrate; and
a second membrane, formed on the second cavity.

16. The MEMS sensor of claim 6, wherein
a second sensor region for a pressure sensor is formed on the substrate, and
the MEMS sensor further includes:
a second cavity, formed in the second sensor region in the substrate; and
a second membrane, formed on the second cavity.

17. The MEMS sensor of claim 8, wherein
a second sensor region for a pressure sensor is formed on the substrate, and
the MEMS sensor further includes:
a second cavity, formed in the second sensor region in the substrate; and
a second membrane, formed on the second cavity.

18. The MEMS sensor of claim 10, wherein
a second sensor region for a pressure sensor is formed on the substrate, and
the MEMS sensor further includes:
a second cavity, formed in the second sensor region in the substrate; and
a second membrane, formed on the second cavity.

19. The MEMS sensor of claim 13, wherein a depth of the first cavity and a depth of the second cavity are different.

20. The MEMS sensor of claim 13, wherein a depth of the first cavity and a depth of the second cavity are same.
